(19) United States
(12) Patent Application Publication
(10) Pub. No.: US 2009/0128509 A1
(43) Pub. Date: May 21, 2009

(54) EXTERNALLY RECONFIGURABLE INPUT SYSTEM

(75) Inventors: Robert A. Kohtz, Cedar Rapids, IA (US); Stephen J. Kelly, Marion, IA (US); Kraig D. Brody, Cedar Rapids, IA (US)

Correspondence Address: SHOOK, HARDY & BACON, L.L.P.;(C/O INTERMEC), INTELLECTUAL PROPERTY DEPARTMENT, 2555 GRAND BLVD., KANSAS CITY, MO, 64108, US

(73) Assignee: INTERMEC IP CORP., Everett, WA (US)

(21) Appl. No.: 12/266,661

(22) Filed: Nov. 7, 2008

Related U.S. Application Data
(60) Provisional application No. 60/989,312, filed on Nov. 20, 2007.

(51) Int. Cl. G06F 3/041; H03M 11/04

(52) U.S. Cl. 345/173; 341/23

(57) ABSTRACT

An externally reconfigurable input system for an electronic device is provided. The input system has the flexibility of receiving input via an input interface with the guidance of key-based substrate overlay positioned proximate a sensor array that is coupled to a printed wiring assembly. An input correlation component receives signals generated by the sensor array in response to displacement of one or more keys associated with the key-based substrate. The key-based substrate overlay is removable so as to be reconfigured.

### CROSS-REFERENCE TO RELATED APPLICATIONS

This application claims priority to U.S. Provisional Patent Application Ser. No. 60/989,312, filed on Nov. 20, 2007.

### BACKGROUND

Modern electronic devices typically have an input interface that takes the form of one or more of a keypad or a touch-sensitive regions (e.g., a touchpad, touch-sensitive display screen, etc.). These devices can be handheld, such as cellular telephones and PDAs or fixed in place, such as vehicular-mounted computers or other fixed devices having a keypad interface. In recent years, advances have been made in the design of touch-sensitive input interfaces employing touch-sensitive regions (referred to herein as “touch interfaces”). Touch interfaces typically have a matrix of sensors spread across the surface of the interface, with an input touch being registered via a measured change in electrical resistance or capacitance across the interface. For instance, the touch interface may be configured to generate an electrostatic field (e.g., with a grid of conductors and adjacent insulators) and measure interference with the field through a capacitive measurement. Through touch interfaces, the user can provide input to the respective electronic device that may correlate to information currently being displayed or outputted by another I/O component of the electronic device (e.g., a screen display, a speaker, etc.). In this way, the touch interface enables dynamic input dependant upon the current operating state of the electronic device, as opposed to static input with some traditional keypads (i.e., each key of the keypad only has one input function).

To provide keypad-like functionality with a touch interface, some modern electronic devices provide a labeled overlay structure permanently affixed over a touch interface. For instance, with cellular telephones, an alphanumeric segmented overlay may be secured over a touch interface. This configuration allows each key of the overlay to be assigned with specific sensors of the touch interface, or otherwise provide, upon touching of the respective key, a distinct “signature” pattern recognized by the touch interface as interaction of the user's finger with the key. While such a configuration serves an intended purpose for many specific types of electronic devices, some other types of electronic/computing devices provide use applications that vary widely depending on the current software product being run on the device. Accordingly, a computing device having a single, permanently affixed overlay structure fails to provide the maximum flexibility for the user with respect to providing touch-related input to the device, whether to a touch interface or other type of interface.

### SUMMARY

An externally reconfigurable input system provides an electronic device with the flexibility of receiving input via an input interface with the guidance of key-based substrate overlay selectable based on applications run on or functionality provided by the electronic device.

In one aspect, a reconfigurable input system includes a key-based substrate overlay formed of a substrate layer, as well as an input key grid coupled with the substrate layer and containing a plurality of key structures. The key-based substrate is held in place by a plastic matrix. The reconfigurable input system also includes a sensor array input field coupled to a printed circuit board of an electronic device, which is overlayed by the substrate layer, as well as an input correlation component stored on the electronic device. The input correlation component receives signals generated by the sensor array in response to displacement of one or more key structures of the plurality of key structures, and interprets the signals as input corresponding to assigned values for the particular key structures displaced.

In another aspect of the present invention, a removable interface overlay for a device having a sensor array input field is provided. The overlay comprises a substrate layer and an input key grid. The substrate layer has opposed surfaces and is configured to overlie the sensor field array input field while the input key grid is coupled with the substrate layer and contains at least a portion of a plurality of key structures.

In yet another aspect of the present invention, a method of receiving input on an electrical device having a sensor array input field coupled to a printed circuit board is disclosed. The method comprises providing a removable interface overlay, placing the overlay over a sensor array input field, displacing one or more of the plurality of key structures from a first position to a second position, with the second position placing the key structure in closer proximity to the sensor array input field. The sensor array input field senses the displacement of the key structure and generates a corresponding signal. The signal is then interpreted as corresponding to an assigned value for the particular key structure that has been displaced.

Additional advantages and novel features of the present invention will in part be set forth in the description that follows or become apparent to those who consider the attached figures or practice the invention.

### BRIEF DESCRIPTION OF THE SEVERAL VIEWS OF THE DRAWINGS

The present invention is described in detail below with reference to the attached drawing figures, wherein:

FIG. 1 is a perspective view of an electronic/computing device in accordance with an embodiment of the present invention;

FIG. 2 is a perspective view of an electronic/computing device including a reconfigurable input system in accordance with an embodiment of the present invention;

FIG. 3 is an exploded view of an electronic/computing device including a reconfigurable input system in accordance with an embodiment of the present invention;

FIG. 4 is a perspective view of a printed circuit board with a sensor array for use in the present invention; and

FIG. 5 is a partial cross section view taken through the device of FIG. 2 in accordance with an embodiment of the present invention.

### DETAILED DESCRIPTION

Embodiments of the present invention support an externally reconfigurable input system enabling a user to select a key-based input overlay best suited to applications run on and/or functionality provided by a respective electronic device. As compared to a traditional, static input grid, the reconfigurable input system provides a more intuitive key arrangement for a multi-purpose electronic or computing device (generically referred to herein as a “device”). In one embodiment, an elastomeric design for the key-based input overlay also blocks environmental contaminants, moisture, and other substances from an input interface of the device, and provide tactile feedback for the user depressing a respective key structure of the input overlay. With certain types of touch interfaces, moisture and debris can interfere with capacitance measurements by the respective interface. Embodiments of the key-based input overlay minimize unwanted interference effects, targeting the user's interaction with the key structures as acceptable input into the device.

As one skilled in the art will appreciate, embodiments of the present invention may be embodied as, or interact with, among other things: a method, system, or computer-program product. Accordingly, certain embodiments may at least partially take the form of a hardware embodiment, a software embodiment, or an embodiment combining software and hardware. In one embodiment, the present invention interacts with a sensor array and a corresponding computer-program product stored on an electronic device, the computer-program product including computer-executable instructions embodied on one or more computer-readable media.

Computer-readable media include both volatile and nonvolatile media, removable and nonremovable media, and contemplates media readable by a database, a switch, and various other network devices. By way of example, and not limitation, computer-readable media comprise media implemented in any method or technology for storing information. Examples of stored information include computer-useable instructions, data structures, program modules, and other data representations. Media examples include, but are not limited to information-delivery media, RAM, ROM, EEPROM, flash memory or other memory technology, CD-ROM, digital versatile discs (DVD), holographic media or other optical disc storage, magnetic cassettes, magnetic tape, magnetic disk storage, and other magnetic storage devices. These technologies can store data momentarily, temporarily, or permanently.

In general terms, certain embodiments relate to a reconfigurable input system including a removable key-based substrate overlay formed of a substrate layer, as well as an input key grid coupled with the substrate layer and containing a plurality of key structures. The reconfigurable input system also includes a sensor array input field coupled to a printed circuit board of an electronic device, which is overlayed by the substrate layer, as well as an input correlation component stored on the electronic device. The input correlation component receives signals generated by the sensor array in response to displacement of one or more key structures of the plurality of key structures towards the sensor array, and interprets the signals as input corresponding to assigned values for the particular key structures displaced. In other words, the input correlation component performs a lookup step to determine the values assigned to each key of the plurality of key structures (corresponding to particular sensors activated), and then registers each occurrence of the user depressing or touching particular keys, enabling the corresponding input to be handled by the electronic device. By way of example, and not limitation, individual keys (or sequence of key activations) may be associated with alphanumeric characters, other symbols, or input commands on the electronic device. For instance, input commands may be a power on/off command, an application software launching or closing command, or any other type of command for interacting with application software running on the electronic device. In certain embodiments, the sensor array is formed as the aforementioned “touch interface”, while in other embodiments, the sensor array is integrated with other types of input interfaces making proximity determinations (e.g., optical sensors, acoustic sensors, inductive sensors, magnetic sensors, pressure sensors, etc.).

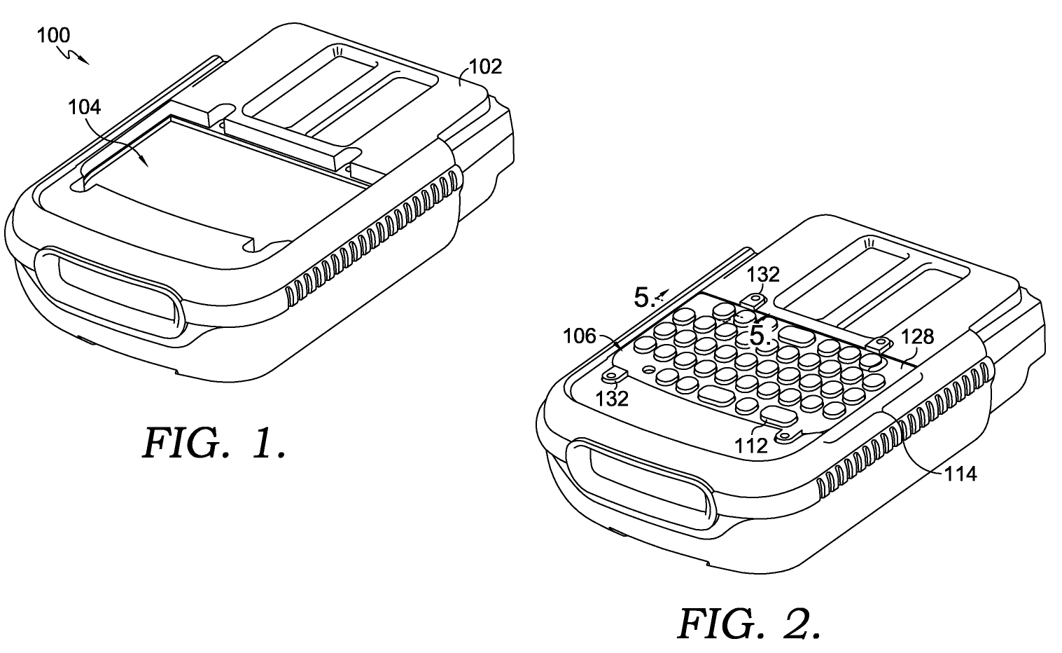

With initial reference to FIGS. 1-3, an exemplary electronic/computing device 100 within or upon which embodiments of the reconfigurable input system of the present invention operate is illustrated. The device 100 is formed with housing shell 102 and a receiving region 104 where a key-based substrate overlay 106 may be positioned. The key-based substrate overlay 106 provides an input interface for a user with respect to the device 100. The housing shell 102 may be fabricated from any durable material that does not affect the performance of the device 100, such as an electrically insulative plastic or other composite material.

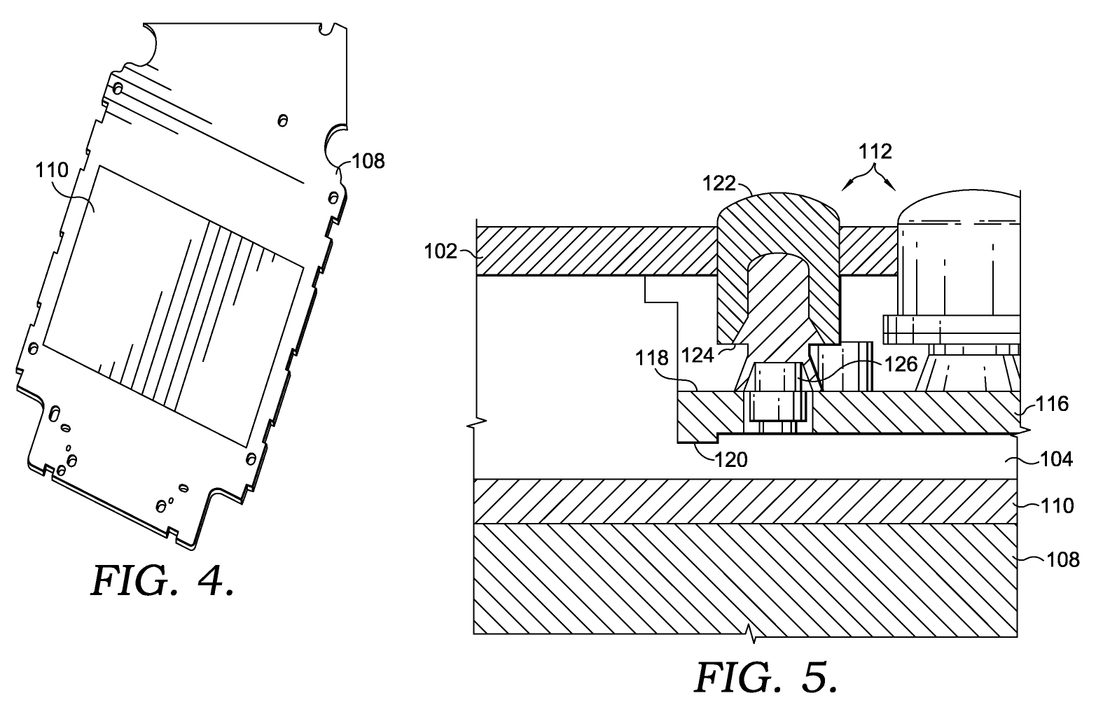

Referring to FIG. 4, the device 100 includes a printed wiring assembly 108, such as a printed circuit board. One or more processors (not shown) and other hardware components of the device 100 reside here (e.g., memory chips), as well as a sensor array 110 coupled with the wiring assembly 108 for detecting interaction with the key-based substrate overlay 106 by a user and generating a corresponding signal for processing by the one or more processors. Sensor arrays can take on many forms and may include alternate arrangements in which sensors may not reside in or on a printed circuit board, but instead on a flexible circuit. Alternatively, a sensor array could also be located over a LCD surface.

For the embodiment shown in FIG. 4, the printed wiring assembly 108 is shown mounted to a surface of the sensor array 110. However, the printed wiring assembly 108 could be integral with the sensor array 110. In embodiments, the sensor array 110 is configured for sensing interaction with the key-based substrate overlay 106 overlying the array 110 at various points across the surface of the array 110. By way of example, and not limitation, the sensory array 110 may be configured for sensing according to one of the following: electrical resistance, capacitance, induction, optical, acoustic, magnetic or applied pressure. As mentioned above, the input correlation component receives the signals generated by the sensor array 110 in response to the user interaction with the key-based substrate overlay 106, and performs a lookup step to determine the value assigned to the particular x-y location on the sensor array 110 (or identification of the individual sensor x-y location). As explained further below, the key-based substrate overlay 106 has a feature that signals to the device 100 the particular layout of the key structures (i.e., key grid), enabling the input correlation component to consult a preestablished reference layout in determining how to interpret signals generated by the sensor array 110.

The sensor array 110 is positioned on the circuit board 108 such that it underlies the receiving region 104 for the key-based substrate overlay 106. In one embodiment, the sensor array 110 is configured to be sufficiently sensitive to register the user's depression of individual key structures 112 of an input key grid 114 of the overlay 106 even though a portion of the housing shell 102 of the device 100 is interdisposed between the array 110 and the overlay 106. In another embodiment where the housing shell 102 is not deemed to be necessary to protect the sensor array 110 from environmental hazards, the key-based substrate overlay 106 may directly lie against the array 110 in the receiving region 104 without any intervening structure.

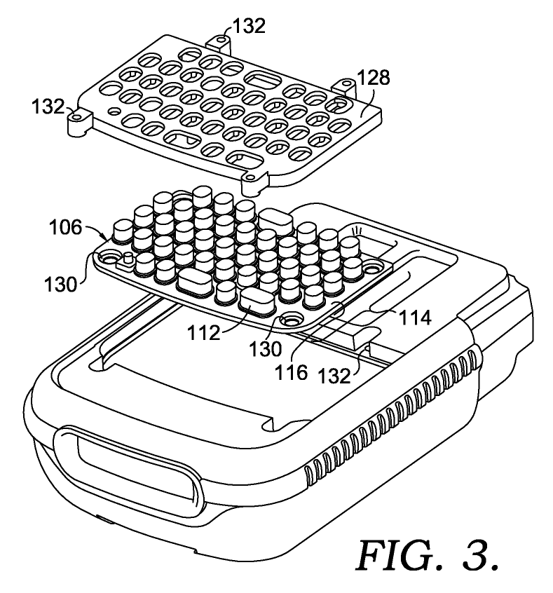

Referring to FIG. 3, the key-based substrate overlay 106 is placed in the receiving region 104 and held in place by an overlying plastic matrix 128. The overlay 106, which is not electrically-coupled to the device 100, can be changed out by removing the matrix 128 and the overlay 106 from the receiving region 104. Matrix 128 is secured in place by fasteners (not shown) passing through openings 132 in the matrix 128 and engaging the receiving region 104. Since the location of the sensor array 110 and circuit board 108 underlie the receiving region 104, all sensitive components of the device 100 are protected from exposure to potentially damaging conditions. This allows for a customer/user of the device 100 to freely change key-based substrate overlay 106 without professional assistance or worrying about potentially damaging the device 100.

The key-based substrate overlay 106 includes a substrate layer 116 into which the input key grid 114 is formed. In certain embodiments, the substrate overlay 106 is preferably formed of an elastomeric material for securely fitting into the receiving region 104 of the device housing shell 102. At least a portion of the individual key structures 112 or region of the substrate layer 116 surrounding the key structures 112 is preferably formed to be more flexible than the remainder of the substrate layer 116, to facilitate the depression of only the individual key structure 112 that is being depressed by the user. For instance, the key structures 112 may possess different material properties than the supporting substrate layer 116 of the substrate overlay 106, or simply the thickness of the key structures 112 (or region of the substrate layer 116 surrounding the key structures 112) may vary from the thickness of the remainder of the substrate layer 116, to provide the intended functionality. It should be understood that the key structures 112 may be coupled with the supporting substrate layer 116 by any mechanical arrangement, to facilitate movement of the key structures 112 orthogonally generally with respect to a plane formed by the substrate layer 116. The key structures 112 may be labeled according to their input function (as captured in the reference layout known to the device 100), as with a traditional key input layout (e.g., a keyboard).

With additional reference to FIG. 5, the substrate layer 116 of the key-based substrate overlay 106 has an upper surface 118 and an opposed lower surface 120, with the lower surface 120 facing the receiving region 104 of the device 100, and thus the sensor array 110. Each individual key structure 112 also has an upper surface 122 for being engaged by a user (e.g., a user's finger) and a lower portion 124 facing the receiving region 104 of the device 100. Upon depression of a respective key structure 112 from a rest or nonactivated position to a second active position, the lower portion 124 thereof moves downwardly and in closer proximity to the sensor array 110. This movement is sensed by one or more individual sensors of the sensor array 110, and through the input correlation component, a particular input is recognized by the device 100. In a certain embodiment, each of the key structures 112 has a proximity element 126 mounted on the lower portion 124 thereof. The proximity structure 126 is designed to serve as an additional element for which movement thereof can be sensed. For instance, the proximity element 126 may be a carbon deposit, or other element that interferes with an electrostatic field generated by the sensor array 110, whereby depression of the respective key structure 112 moves the proximity element 126 closer to the array 110. This provides improves sensitivity over the sensor array 110 merely measuring the presence or proximity of a user's finger depressing the respective key structure 112.

The orientation of the key structures 112 can also be located generally perpendicular to those shown in FIGS. 2 and 4. Examples of such orientation would be for key structures located on the side of a device such as volume control or other buttons for a wireless mobile phone. An array of key structures 112 can be arranged so that when the key travels up away from the sensor such a movement can trigger a key indication. Furthermore, it is also possible that only a proximity can trigger the sensor or a touch by a finger or a stylus

In another example, the proximity element 126 may be any element that improves the ability of optical or acoustic sensors of the sensor array 110 to detect movement of key structures 112. For instance, the proximity element 126 may be selected to improve the reflectivity of light waves (e.g., infrared or other frequency) or sound waves generated by a component of the device 100 and sensed by the sensor array 110 as reflections off of the key-based substrate overlay 106, in determining proximity of the lower portion 124 of a respective key structure 112 (i.e., signaling the user depressing a particular key).

The lower surface 120 of the key-based substrate overlay 106 may be formed with a feature in the form of a key grid layout indicator, which functions to inform the device 100 of particular layout of the input key grid 114. In this way, a particular key structure 112 depression sensed by the sensor array 110 can be registered by the device 100 as a certain kind of input (e.g., an alphanumeric key selection, a command selection for a particular application currently running on the device 100, etc.), since the key-based substrate overlay 106 and associated input key grid 114 is not permanently affixed to the device 100. Thus, the key grid layout indicator provides automatic indication to the device 100 of the particular key grid layout for the substrate overlay 106 that has been placed over the receiving region 104. Accordingly, interchangability of key-based substrate overlays 106 having different input key grid 114 layouts is supported without the user having to manually enter input key grid layout information on the device 100. In one arrangement, the key grid layout indicator is formed as a series of projections and depressions in the overlay lower surface 120. The pattern of projections and depression is sensed by the sensing array 110, and upon mapping the particular pattern, the input correlation component consults a preestablished reference layout corresponding to the mapped pattern in order to find the input key grid 114 layout for the substrate overlay 106. In a sense, the key grid layout indicator may be considered a binary or similar code interpreted by the device 100, with the particular code associated with a corresponding input key grid 114 layout.

A further enhancement to the present invention is a plurality of light-emitting diodes (LED's) that are positioned to illuminate the receiving region 104. The LED's are typically located about the periphery of the receiving region 104 and are incorporated into the circuit board 108. To aid in illumination, the material of the receiving region 104 can be a translucent plastic which will permit more light to pass therethrough so as to improve lighting to the individual key structures 112. It is also envisioned that the individual key structures 112 could also be translucent.

Since certain changes may be made in the above invention without departing from the scope hereof, it is intended that all matter contained in the above description or shown in the accompanying drawing be interpreted as illustrative and not in a limiting sense. It is also to be understood that the following claims are to cover certain generic and specific features described herein.

What is claimed is:

1. A reconfigurable input system, comprising:
a sensor array input field coupled to a printed wiring assembly of an electronic device;
a removable substrate layer configured for overlying the sensor array;
an input key grid coupled with the substrate layer and containing a plurality of key structures; and
an input correlation component stored on the electronic device, and configured for receiving signals generated by the sensor array in response to displacement of one or more key structures of the plurality of key structures towards the sensor array, and interpreting the signals as input corresponding to assigned values for the particular one or more key structures displaced.

2. The system of claim 1, wherein the plurality of key structures of the input key grid possesses an upper user engagement surface and a lower portion, each key structure of the plurality of key structures having a proximity element coupled to the lower portion of the respective key structure.

3. The system of claim 2, wherein the proximity element is a carbon deposit.

4. The system of claim 2, wherein the input key grid is configured such that the plurality of key structures are capable of being individually displaced from a first rest position to a second active position where the respective proximity element is moved closer to the sensor array input field.

5. The system of claim 4, wherein the sensor array input field is configured to provide one or more of capacitance sensing and electrical resistance sensing.

6. The system of claim 1, wherein the sensor array input field is configured to provide one or more of capacitance sensing, electrical resistance sensing, inductive sensing, magnetic sensing, optical sensing, acoustical sensing, pressure sensing, and resonance sensing.

7. The system of claim 1, wherein the substrate layer has a key grid layout indicator capable of being sensed by the sensor array to indicate to the input correlation component a pre-established arrangement of the input key grid.

8. The system of claim 1, wherein the input key grid is an elastomeric input key grid.

9. The system of claim 1, wherein the system further comprises one or more light-emitting diodes for providing a backlight to the input key grid.

10. A removable interface overlay for a device possessing a sensor array input field, the overlay comprising:
a substrate layer having a first surface and an opposed second surface, and configured to overlie the sensor array input field;
an input key grid coupled with the substrate layer and containing on at least a portion thereof a plurality of key structures, each key structure having an upper user engagement surface and a lower portion and being configured for individual displacement from a first rest position to a second active position in closer proximity to the first surface of the substrate layer.

11. The overlay of claim 10, wherein each key structure of the plurality of key structures has a proximity element coupled to the lower portion of the respective key structure.

12. The overlay of claim 10, wherein the sensor array is configured to provide one or more of capacitance sensing, electrical resistance sensing, inductive sensing, magnetic sensing, optical sensing, acoustical sensing, pressure sensing, and resonance sensing.

13. The system of claim 10, wherein the second surface of the substrate layer has a key grid layout indicator for being sensed by the sensor array to indicate pre-established functions of the input key grid.

14. The system of claim 10, wherein the input key grid is an elastomeric input key grid.

15. A method of receiving input on an electrical device having a sensor array input field coupled to a printed wiring assembly, comprising:
providing a removable interface overlay having:
a substrate layer having a first surface and an opposed second surface; and
an input key grid coupled with the substrate layer and containing on at least a portion thereof a plurality of key structures, each key structure having an upper user engagement surface and a lower portion and being configured for individual displacement from a first rest position to a second active position;
placing the removable interface overlay over the sensor array input field;
displacing one or more of the plurality of key structures from the first position to the second position, whereby the displaced one or more key structures are in closer proximity to the sensor array input field;
sensing, via the sensor array input field, the displacement of the particular one or more of the plurality of key structures and generating corresponding signals;
receiving the signals generated by the sensor array and interpreting the signals as input corresponding to assigned values for the particular one or more of the plurality of key structures displaced.

16. The method of claim 15, wherein each key structure of the plurality of key structures has a proximity element coupled to the lower portion of the respective key structure.

17. The method of claim 16, wherein the proximity element is a carbon deposit.

18. The method of claim 15, wherein the substrate layer has a key grid layout indicator capable of being sensed by the sensor array input field to indicate a pre-established arrangement of the input key grid.

19. The method of claim 15, wherein the input key grid is an elastomeric input key grid.

20. The method of claim 15, wherein the input received is reconfigurable based on an arrangement of the interface overlay.
